(19) United States
(12) Patent Application Publication
(10) Pub. No.: US 2025/0102637 A1
(43) Pub. Date: Mar. 27, 2025

(54) LIGHT BEAM SCANNING DEVICE AND DISTANCE MEASURING DEVICE

(71) Applicant: Mitsubishi Electric Corporation, Tokyo (JP)

(72) Inventors: Masayuki OMAKI, Chiyoda-ku, Tokyo (JP); Natsuki HONDA, Chiyoda-ku, Tokyo (JP); Shota NAKAHARA, Chiyoda-ku, Tokyo (JP)

(73) Assignee: Mitsubishi Electric Corporation, Tokyo (JP)

(21) Appl. No.: 18/724,622

(22) PCT Filed: Jan. 18, 2022
(86) PCT No.: PCT/JP2022/001602

§ 371 Date: Jun. 27, 2024

(51) Int. Cl. G01S 7/481; G01S 17/08; G02B 26/10; G02B 27/09

(52) U.S. Cl. CPC G01S 7/4817; G01S 7/4815; G01S 17/08; G02B 26/105; G02B 27/0955

(57) ABSTRACT

A light beam scanning device includes a plurality of light sources, a plurality of beam shapers, a scanning mirror, and a scanning region correction optical member. The plurality of light sources emit a plurality of light beams. Each of the plurality of beam shapers includes a first lens and a second lens. A distance between the first lens and the second lens in the beam shaper that shapes the light beam is different from a distance between the first lens and the second lens in the beam shaper that shapes the light beam.

### TECHNICAL FIELD

The present disclosure relates to a light beam scanning device and a distance measuring device.

### BACKGROUND ART

WO 2018/021108 (PTL 1) discloses a scanning illumination device equipped with a light emitting device and a projection optical system. The light emitting device includes a laser diode, an optical deflection unit, a wavelength conversion unit, and a light focusing unit. The light focusing unit includes a first optical system and a second optical system. The first optical system includes an aspheric lens and a cylindrical lens. The cylindrical lens of the first optical system has a curvature with respect to a fast axis of a laser beam emitted from the laser diode. The second optical system includes a cylindrical lens. The cylindrical lens of the second optical system has a curvature with respect to a slow axis of the laser beam.

### CITATION LIST

### Patent Literature

PTL 1: WO 2018/021108

### SUMMARY OF INVENTION

### Technical Problem

An object of a first aspect of the present disclosure is to provide a light beam scanning device which has a plurality of scanning regions and is capable of reducing distortion or the like of the scanning regions and emitting light beams with improved quality. An object of a second aspect of the present disclosure is to provide a distance measuring device with improved measurement accuracy.

### Solution to Problem

The light beam scanning device of the present disclosure includes a plurality of light sources, a plurality of beam shapers, a scanning mirror, and a scanning region correction optical member. The plurality of light sources emit a plurality of light beams. Each of the plurality of light beams is emitted from a corresponding light source of the plurality of light sources and has a larger light beam diameter in a fast axis direction than in a slow axis direction. Each of the plurality of beam shapers is provided for a corresponding light source of the plurality of light sources and shapes a light beam emitted from the corresponding light source. The scanning mirror scans the plurality of light beams shaped by the plurality of beam shapers. The scanning region correction optical member corrects at least one of a plurality of scanning regions formed by the plurality of light beams scanned by the scanning mirror. Each of the plurality of beam shapers includes a first lens and a second lens. The first lens is disposed closer to a corresponding light source of the plurality of light sources than the second lens. Each of the plurality of beam shapers gives a positive refractive power to a corresponding light source of the plurality of light beams in both the slow axis direction and the fast axis direction. Each of the beam shapers has a focal length Ff in the fast axis direction and a focal length Fs in the slow axis direction greater than the focal length Fs. In at least one direction, an incident angle θ1 of the first light beam, which is one of the plurality of light beams, on the scanning mirror when the scanning mirror is positioned in the center of a rotation range of the scanning mirror is different from an incident angle θ2 of a second light beam, which is one of the plurality of light beams, on the scanning mirror when the scanning mirror is positioned in the center of the rotation range of the scanning mirror. A distance D₁ between the first lens and the second lens in the first beam shaper which is one of the plurality of beam shapers and shapes the first light beam is different from a distance D₂ between the first lens and the second lens in the second beam shaper which is one of the plurality of beam shapers and shapes the second light beam.

The distance measuring device of the present disclosure includes the light beam scanning device of the present disclosure.

### Advantageous Effects of Invention

The light beam scanning device of the present disclosure includes a scanning region correction optical member. Therefore, the light beam scanning device of the present disclosure can correct the distortion or the like of the scanning region caused by the difference in the incident angle of the light beam incident on the scanning mirror. The light beam scanning device of the present disclosure also includes a beam shaper, and the beam shaper includes a first lens and a second lens. The distance between the first lens and the second lens is different between two beam shapers that shape two light beams incident on the scanning mirror with different incident angles. Therefore, the quality of the light beam output from the scanning region correction optical member, for example, the parallelism of the light beam output from the scanning region correction optical member is improved.

### BRIEF DESCRIPTION OF DRAWINGS

FIG. 1 is a perspective view schematically illustrating a light beam scanning device according to a first embodiment;

FIG. 2 is a side view schematically illustrating the light beam scanning device according to the first embodiment;

FIG. 3 is a top view schematically illustrating the light beam scanning device according to the first embodiment;

FIG. 4 is a perspective view schematically illustrating a light source included in the light beam scanning device according to the first embodiment;

FIG. 5 is a perspective view schematically illustrating a beam shaper included in the light beam scanning device according to the first embodiment;

FIG. 6 is a plan view schematically illustrating a beam shaper included in the light beam scanning device according to the first embodiment in a fast axis;

FIG. 7 is a plan view schematically illustrating a beam shaper included in the light beam scanning device according to the first embodiment in a slow axis;

FIG. 8 is a diagram schematically illustrating a relationship between an incident angle of a light beam with respect to a reflection surface of a scanning mirror and a scanning trajectory of the light beam reflected by the reflection surface;

FIG. 9 is a perspective view schematically illustrating a light beam scanning device according to a first comparative example;

FIG. 10 is a side view schematically illustrating the light beam scanning device according to the first comparative example;

FIG. 11 is a top view schematically illustrating the light beam scanning device according to the first comparative example;

FIG. 12 is a diagram illustrating a plurality of scanning regions generated by the light beam scanning device according to the first comparative example;

FIG. 13 is a perspective view schematically illustrating a light beam scanning device according to a second comparative example;

FIG. 14 is a front view schematically illustrating the light beam scanning device according to the second comparative example;

FIG. 15 is a plan view schematically illustrating the light beam scanning device according to the second comparative example;

FIG. 16 is a diagram illustrating a plurality of scanning regions generated by the light beam scanning device according to the first embodiment;

FIG. 17 is a diagram illustrating a relationship between a width of an emitter (light emitting point), a focal length of a lens optical system, and a spread angle of a light beam passing through the lens optical system;

FIG. 18 is a perspective view schematically illustrating another example of the light beam scanning device according to the first embodiment;

FIG. 19 is a front view schematically illustrating another example of the light beam scanning device according to the first embodiment;

FIG. 20 is a plan view schematically illustrating another example of the light beam scanning device according to the first embodiment;

FIG. 21 is a perspective view schematically illustrating a light beam scanning device according to a third comparative example;

FIG. 22 is a plan view schematically illustrating the light beam scanning device according to the third comparative example; and

FIG. 23 is a diagram schematically illustrating a distance measuring device according to a second embodiment.

### DESCRIPTION OF EMBODIMENTS

Hereinafter, embodiments of the present disclosure will be described. The same components are denoted by the same reference numerals, and the description thereof will not be repeated.

### First Embodiment

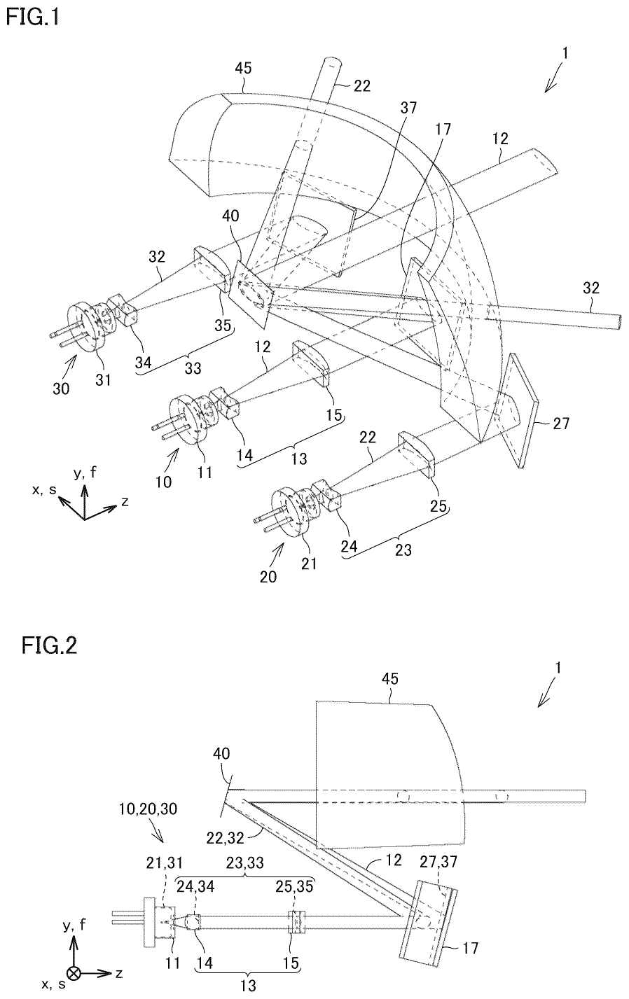

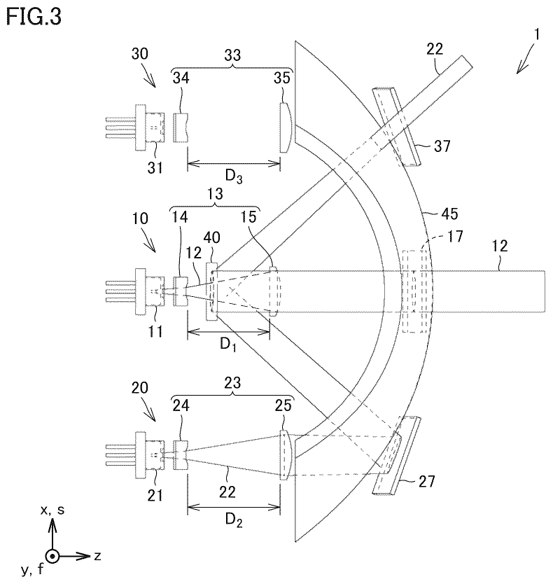

A light beam scanning device 1 according to a first embodiment will be described with reference to FIGS. 1 to 8. FIGS. 1 to 3 schematically illustrate an example configuration of the light beam scanning device 1 according to the first embodiment. FIG. 1 is a perspective view schematically illustrating the light beam scanning device 1, FIG. 2 is a side view schematically illustrating the light beam scanning device 1, and FIG. 3 is a top view schematically illustrating the light beam scanning device 1. The light beam scanning device 1 mainly includes a plurality of light sources (for example, light sources 11, 21, and 31), a plurality of beam shapers (for example, beam shapers 13, 23, and 33), a scanning mirror 40, and a scanning region correction optical member 45. The light beam scanning device 1 may further include reflection mirrors 17, 27 and 37.

In the present embodiment, each of the plurality of beam shapers is provided for a corresponding light source of the plurality of light sources. Hereinafter, a group of a light source and a beam shaper may be referred to as a light source module. For example, the light beam scanning device 1 includes three light source modules (light source modules 10, 20, and 30). The light source module 10 includes a light source 11 and a beam shaper 13. The light source module 20 includes a light source 21 and a beam shaper 23. The light source module 30 includes a light source 31 and a beam shaper 33. The beam shaper 13 corresponds to the light source 11. The beam shaper 23 corresponds to the light source 21. The beam shaper 33 corresponds to the light source 31. Although the light beam scanning device 1 is described to include three light sources, the light beam scanning device 1 may include two light sources, or may include four light sources or more. The number of beam shapers included in the light beam scanning device 1 corresponds to the number of light sources.

### <Light Sources 11, 21, 31>

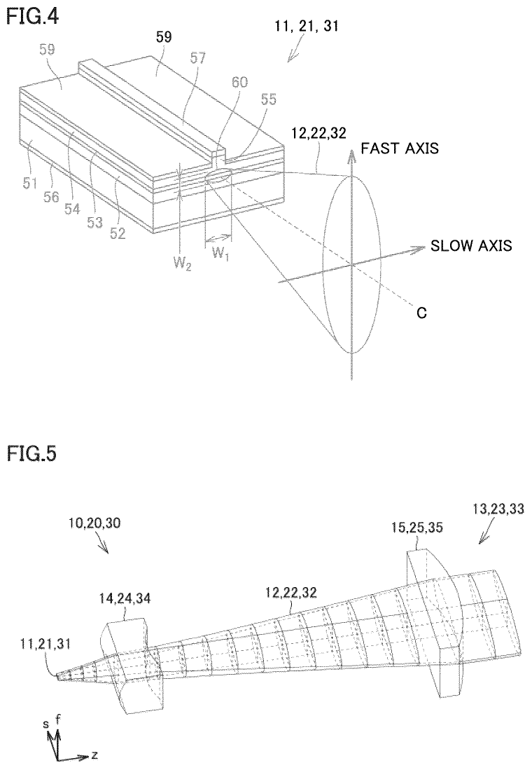

As illustrated in FIG. 1, a plurality of light sources (for example, light sources 11, 21, and 31) emit a plurality of light beams (for example, light beams 12, 22, and 32). Each of the plurality of light beams is emitted from a corresponding light source of the plurality of light sources. Specifically, the light source 11 emits a light beam 12. The light source 21 emits a light beam 22. The light source 31 emits a light beam 32. As illustrated in FIGS. 4, 6 and 7, each of the plurality of light beams has a larger light beam diameter in the fast axis direction than in the slow axis direction. Hereinafter, the light source 11 is used as an example to describe the structure and function of each of the plurality of light sources. Unless otherwise specified, other light sources (for example, the light sources 21 and 31) are the same as the light source 11.

The light source 11 is, for example, a laser diode, and the light beam 12 is, for example, a laser beam. FIG. 4 is a perspective view schematically illustrating a laser diode as an example of the light sources 11, 21 and 31. The laser diode includes a substrate 51, a cladding layer 52, an active layer 53, a cladding layer 54, an electrode 56, an electrode 57, and an insulating layer 59. The cladding layer 52 is formed on the substrate 51. The active layer 53 is formed on the cladding layer 52. The cladding layer 54 is formed on the active layer 53. The active layer 53 is sandwiched between the cladding layer 52 and the cladding layer 54. The electrodes 56 and 57 are electrodes that apply a forward voltage to the cladding layer 52 and the cladding layer 54. The electrode 56 is formed on the substrate 51. The electrode 56 may be formed on the cladding layer 52 rather than on the substrate 51. The electrode 57 is formed on the cladding layer 54. The cladding layer 54 is formed with a ridge portion 55 (also referred to as a contact layer) which limits a current to flow through this portion so as to cause laser oscillation in this ridge portion, and the electrode 57 is formed on the ridge portion 55.

When a voltage is applied to the electrodes 56 and 57, a light beam is emitted from the active layer 53. As illustrated in FIG. 4, a width W₁ of an emitter 60 (a length of the active layer 53 in the width direction) which is a light emitting point of the light beam from the active layer 53 is greater than a width W₂ of the emitter 60 (a length of the active layer 53 in the thickness direction). In a cross section perpendicular to the optical axis of the emitted light beam (direction parallel to the z-axis in the figure), the thickness direction of the active layer 53 corresponds to the fast axis (f-axis in FIGS. 5 to 7) direction of the light beam 12, and the width direction of the active layer 53 corresponds to the slow axis (s-axis in FIGS. 5 to 7) direction of the light beam 12.

As illustrated in FIG. 4, when the width W₁ of the emitter (the light emitting point) 60 in the slow axis direction is greater than the width W₂ of the emitter 60 in the fast axis direction, the light beam diameter of an emitted light beam is larger in the fast axis direction than in the slow axis direction, and the quality of the light beam in the fast axis direction is higher than the quality of the light beam in the slow axis direction. When the light source 11 is a multi-emitter laser diode including a plurality of emitters, the width W₁ of the emitter is the total width of the plurality of emitters.

The light source 11 may be, for example, a laser diode that emits a light beam 12 having a high output of 0.5 W or more. The light source 11 may be, for example, a multi-mode laser diode. The multi-mode laser diode can emit a light beam 12 having a higher output than a single mode laser diode. In the present embodiment, the light source 11 may be a laser diode in which the oscillation mode in the slow axis is multi-mode and the oscillation mode in the fast axis is single mode.

### <Beam Shapers 13, 23, 33>

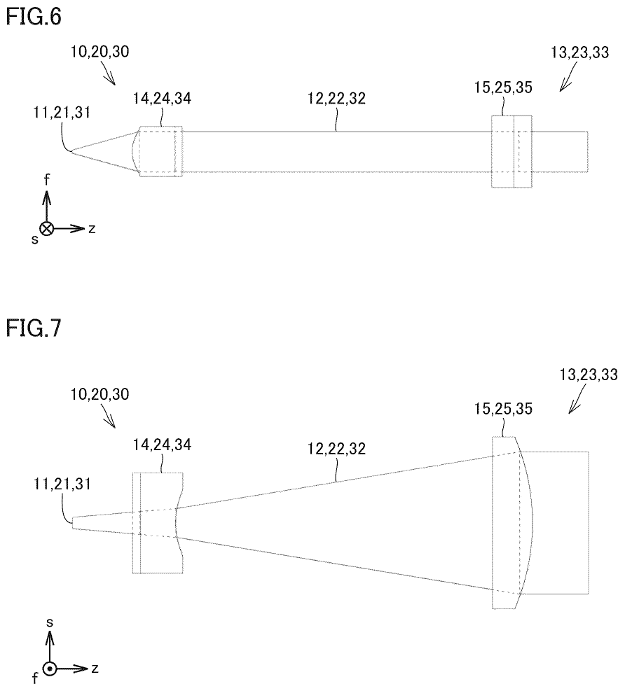

FIGS. 5 to 7 are explanatory diagrams illustrating a plurality of beam shapers (the beam shapers 13, 23, and 33) as an example. FIG. 5 is a perspective view schematically illustrating a beam shaper, FIG. 6 is a plan view schematically illustrating the beam shaper in the fast axis, and FIG. 7 is a plan view schematically illustrating the beam shaper in the slow axis. Each of the plurality of beam shapers shapes a light beam emitted from a corresponding light source. The shaping of a light beam includes changing a divergence angle of the optical beam and a beam width of the light beam accordingly. Each of the plurality of beam shapers is used in the light beam scanning device 1 mainly for the purpose of improving the parallelism of a light beam incident on the scanning region correction optical member 45. For example, each of the plurality of beam shapers is used to collimate a light beam incident on the scanning region correction optical member 45. In the present embodiment, each beam shaper may not collimate each incident light beam strictly. This is because it is important that each of the plurality of light beams output from the scanning region correction optical member 45 is substantially parallel. Therefore, in the present embodiment, each of the plurality of beam shapers includes a plurality of lenses, and is configured to easily adjust the beam shaping ability of each of the plurality of beam shapers by adjusting the distance between the plurality of lenses.

As illustrated in FIGS. 5 to 7, each of the plurality of beam shapers includes a front lens and a rear lens. The front lens may be referred to as a first lens of the beam shaper, and the rear lens may be referred to as a second lens of the beam shaper. As illustrated in FIG. 1, the beam shaper 13 shapes the light beam 12. The beam shaper 13 includes a front lens 14 and a rear lens 15. In the beam shaper 13, the front lens 14 and the rear lens 15 are separated from each other by a distance D₁. The beam shaper 23 shapes the light beam 22 emitted from the light source 21. The beam shaper 23 includes a front lens 24 and a rear lens 25. In the beam shaper 23, the front lens 24 and the rear lens 25 are separated from each other by a distance D₂. The beam shaper 33 shapes the light beam 32 emitted from the light source 31. The beam shaper 33 includes a front lens 34 and a rear lens 35. In the beam shaper 33, the front lens 34 and the rear lens 35 are separated from each other by a distance D₃. Hereinafter, the beam shaper 13 is used as an example to describe the structure and function of the beam shaper. Unless otherwise specified, other beam shapers (for example, the beam shapers 23 and 33) are the same as the beam shaper 13.

The front lens 14 of the beam shaper 13 is disposed closer to the light source 11 than the rear lens 15 on the optical path of the light beam 12. In other words, the front lens 14 is disposed between the light source 11 and the rear lens 15. In the present embodiment, each of the front lens 14 and the rear lens 15 may not be a single lens. In other words, the beam shaper 13 may include a plurality of lenses (a first optical system) as the front lens 14 and a plurality of lenses (a second optical system) as the rear lens.

In the present embodiment, the beam shaper 13 gives a positive refractive power to the light beam 12 in both the slow axis direction and the fast axis direction of the light beam 12 incident on the beam shaper 13. The focal length of the beam shaper 13 (more specifically, the composite focal length of the front lens 14 and the rear lens 15) in the slow axis direction is greater than the focal length of the beam shaper 13 in the fast axis direction. In other words, the refractive power of the beam shaper 13 in the fast axis direction of the light beam 12 is greater than the refractive power of the beam shaper 13 in the slow axis direction of the light beam 12. The beam shaper 13 may collimate the light beam 12 in the fast axis direction of the light beam 12.

In the present embodiment, as described with respect to the composite focal length of the beam shaper 13, the focal length of a composite lens constituted by a combination of two or more lenses is defined as a distance from a focal point, i.e., a point at which light beams output from one point are collimated into parallel light beams by the composite lens (a group of lenses constituting the composite lens) or a point at which the parallel light beams are focused by the composite lens (a group of lenses constituting the composite lens) to the center of the group of lenses. In other words, the “focal length” in the present disclosure does not mean a distance by which the light beams are actually focused at a focal point (a focal length in a broad sense) but an intrinsic value determined by the specifications of a lens (in the case of a composite lens, the specifications of a group of lenses constituting the composite lens). The same applies to the focal length of a single lens. In other words, the focal length of a single lens is defined as a distance from a focal point, i.e., a point at which light beams output from one point are collimated into parallel light beams by the single lens or a point at which the parallel light beams are focused by the single lens to the center of the single lens.

The front lens of each beam shaper has a positive refractive power in the fast axis direction of the light beam. The rear lens of each beam shaper has a positive refractive power in the slow axis direction of the light beam. For example, the front lens may have a lens surface with a positive curvature in the fast axis of the light beam (for example, a convex surface on the incident side of the front lens 14, 24, 34 in FIG. 6). For example, the rear lens may have a lens surface with a positive curvature in the slow axis of the light beam (for example, a convex surface on the output side of the rear lens 15, 25, 35 in FIG. 7). In this case, the light beam is shaped mainly by the front lens in the fast axis direction, and is shaped mainly by the rear lens in the slow axis direction.

The focal length F2s of the rear lens (the distance from the center of the rear lens to the focal point of the rear lens) in the slow axis direction may be greater than the focal length F1f of the front lens (the distance from the center of the front lens to the focal point of the front lens) in the fast axis direction. In other words, the refractive power of the front lens in the fast axis direction may be greater than the refractive power of the rear lens in the slow axis direction. Preferably, the rear lens has a zero refractive power in the fast axis direction. For example, the incident surface of the rear lens may be a plane perpendicular to the optical axis of the light beam.

As described above, the lens (for example, the front lens) which mainly shapes the light beam (mainly changes the spread angle of the light beam so as to substantially collimate the light beam) in the fast axis direction is different from the lens (for example, the rear lens) which mainly shapes the light beam in the slow axis direction. Therefore, the influence of the distance between the lenses in the beam shaper (specifically, the distance between the front lens and the rear lens) on the light beam shaping effect of the beam shaper can be significantly reduced. As illustrated in FIGS. 5 to 7, in each of the plurality of beam shapers, the divergence angle of the light beam incident on the front lens in the slow axis direction is smaller than the divergence angle of the light beam incident on the front lens in the fast axis direction, and the divergence angle of the light beam incident on the rear lens in the slow axis direction is greater than the divergence angle of the light beam incident on the rear lens in the fast axis direction.

In a beam shaper, when the distance between the front lens and the rear lens is changed without changing the distance between the light source and the front lens, the light beam in the slow axis direction is affected by the change in the distance between the front lens and the rear lens, but the light beam in the fast axis direction is not affected by a change in the distance between the front lens and the rear lens. Therefore, if the light beam is collimated to a small light beam diameter by using the front lens in the fast axis direction in which the quality of the light beam is relatively good, the spread angle of the light beam output from the beam shaper in the slow axis direction can be adjusted while keeping the light beam in a shaped state in the fast axis direction simply by changing the distance between the front lens and the rear lens. This function of the beam shaper is particularly effective in the case where the refractive power given to the light beam in the slow axis direction by the scanning region correction optical member 45 differs depending on the incident position of the light beam on the scanning region correction optical member 45. In other words, according to the above configuration, the parallelism of the light beam output from the scanning region correction optical member 45 can be improved by changing the distance between the front lens and the rear lens (the distance D₁, D₂, or D₃) in a beam shaper.

In the present embodiment, the distance between the front lens and the rear lens is made different between a plurality of beam shapers that output a plurality of light beams whose incident angles on the scanning mirror 40 are different (therefore, whose incident positions on the scanning region correction optical member 45 are different) based on the function of the beam shaper described above and the function of the scanning region correction optical member 45 to be described later. In the present embodiment, the incident angle of the light beam incident on the scanning mirror 40 is an angle formed by the normal line of the reflection surface of the scanning mirror 40 and the optical axis of the light beam incident on the scanning mirror 40 when the scanning mirror 40 is positioned at the center of a rotation range (hereinafter referred to as the “rotation center”) of the scanning mirror 40. Hereinafter, the normal line of the reflection surface of the scanning mirror 40 when the scanning mirror 40 is positioned at the rotation center thereof may be referred to as a first normal line of the scanning mirror 40.

In at least the x axis direction (see FIGS. 1 to 3), the incident angle of the light beam 22 incident on the scanning mirror 40 is different from the incident angle of the light beam 12 incident on the scanning mirror 40. In at least the x axis direction, the incident angle of the light beam 32 incident on the scanning mirror 40 is different from the incident angle of the light beam 12 incident on the scanning mirror 40. More specifically, the incident angle of the light beam 22 is greater than the incident angle of the light beam 12. The incident angle of the light beam 32 is greater than the incident angle of the light beam 12. In the present embodiment, the light source module 20 and the reflection mirror 27 are disposed with respect to the light source module 30 and the reflection mirror 37 in such a manner that the optical path of the light beam 22 and the optical path of the light beam 32 are plane symmetrical with respect to a vertical plane (yz plane) including the optical path of the light beam 12. Therefore, the incident angle of the light beam 22 incident on the scanning mirror 40 is the same as the incident angle of the light beam 32 incident on the scanning mirror 40. In this case, the distance D₂ between the front lens 24 and the rear lens 25 in the beam shaper 23 that shapes the light beam 22 is different from the distance D₁ between the front lens 14 and the rear lens 15 in the beam shaper 13 that shapes the light beam 12. The distance D₃ between the front lens 34 and the rear lens 35 in the beam shaper 33 that shapes the light beam 32 is different from the distance D₁. The distance D₃ is equal to the distance D₂.

In the present embodiment, the x axis direction may be a direction parallel to the slow axis direction of each light beam, may be a horizontal direction (in the present embodiment, the horizontal direction includes not only a direction perpendicular to the vertical direction but also a horizontal direction defined in a host device (such as an automobile vehicle) on which the light beam scanning device 1 is mounted), may be any direction on a plane perpendicular to the rotation axis of the scanning mirror 40 (for example, one direction perpendicular to the rotation axis of the scanning mirror 40, or a direction in which a difference between the incident angles of the plurality of light beams on the scanning mirror 40 is the largest), or may be a direction in which the scanning region is widened in the light beam scanning device 1 (for example, a longitudinal direction of the entire scanning region of the light beam scanning device 1). The slow axis direction of each light beam and the x axis direction do not necessarily coincide with each other. In other words, in the present embodiment, the slow axis of each light beam is identical to the horizontal direction and the fast axis of each light beam is identical to the vertical direction (i.e., perpendicular to the horizontal direction), but the present disclosure is not limited thereto.

In the present embodiment, the incident angles of the light beams incident on the scanning mirror 40 are the same in the vertical direction (y direction) and are different from each other in the horizontal direction (for example, x direction). Therefore, the incident angle of each light beam incident on the scanning mirror 40 is determined in two dimensions. On the other hand, when the incident angles of the light beams incident on the scanning mirror 40 are different from each other in both the horizontal direction and the vertical direction, the incident angle of each light beam incident on the scanning mirror 40 is determined in three dimensions.

As illustrated in FIG. 7, in the present embodiment, the front lens has a negative refractive power in the slow axis direction. For example, the output surface of each front lens 14, 24, or 34 is a concave surface having a negative curvature in the slow axis direction. The front lens increases the spread angle of the light beam in the slow axis direction. Thus, even when the distance between the front lens and the rear lens is short, the focal length (composite focal length) Fs of the beam shaper in the slow axis direction can be effectively increased. The shape of the front lens is not limited to the shape mentioned above, and may be, for example, a shape having no curvature or a positive curvature in the slow axis direction.

Hereinafter, an example of adjusting the distance between the front lens and the rear lens in each of the plurality of beam shapers will be described.

The light beam 12 shaped by the beam shaper 13 is reflected by the reflection mirror 17, and is incident on the scanning mirror 40. The light beam 22 shaped by the beam shaper 23 is reflected by the reflection mirror 27, and is incident on the scanning mirror 40. The light beam 32 shaped by the beam shaper 33 is reflected by the reflection mirror 37, and is incident on the scanning mirror 40. In other words, each of the reflection mirrors (the reflection mirrors 17, 27, and 37) is disposed in such a manner that the light beams 12, 22, and 32 are incident on the single scanning mirror 40. In the present embodiment, the reflection mirror 27 and the reflection mirror 37 are disposed symmetrically with respect to a vertical plane including the optical path of the light beam 12.

When being rotated around the rotation axis of the scanning mirror 40, the scanning mirror 40 reflects the light beams 12, 22, and 32 shaped by the beam shapers 13, 23, and 33, respectively. The light beams 12, 22, and 32 reflected by the scanning mirror 40 travel toward the outside of the light beam scanning device 1. As described above, the scanning mirror 40 is rotated to reflect the plurality of light beams 12, 22, and 32, whereby the light beams 12, 22, and 32 are scanned. The scanning mirror 40 may be, for example, a microelectromechanical system (MEMS) mirror which can electrically control the tilt angle of the reflection surface of the scanning mirror 40. The scanning mirror 40 may be, for example, an electromagnetic MEMS mirror in which the tilt angle of the reflection surface can be controlled by an electromagnetic force generated by a coil, or a piezoelectric MEMS mirror in which the tilt angle of the reflection surface can be controlled by using a piezoelectric member. By controlling the tilt angle of the reflection surface of the scanning mirror 40, it is possible to change an output angle of each of the light beams 12, 22, and 32 output from the light beam scanning device 1 (the direction in which each of the light beams 12, 22, and 32 is output, and more specifically, an angle between the first normal line of the scanning mirror 40 and the optical axis of each of the light beams 12, 22, and 32 output from the scanning mirror 40).

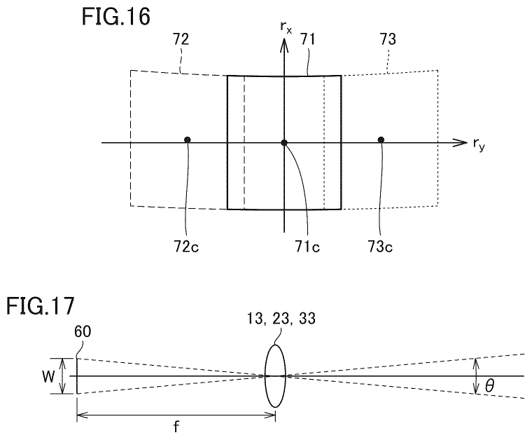

The scanning mirror 40 may be rotated about two rotation axes parallel to the reflective surface of the scanning mirror 40 and orthogonal to each other. In the present embodiment, one rotation axis of the scanning mirror 40 is parallel to the x axis, and the other rotation axis of the scanning mirror 40 is parallel to the y axis. The scanning mirror 40 scans each of the light beams 12, 22, and 32 in the x axis direction and the y axis direction. The light beam 12 scanned by the scanning mirror 40 irradiates a scanning region 71 (see FIG. 16). The light beam 22 scanned by the scanning mirror 40 irradiates a scanning region 72 (see FIG. 16). The light beam 32 scanned by the scanning mirror 40 irradiates a scanning region 73 (see FIG. 16). By controlling the tilt angle of the reflection surface of the scanning mirror 40 about two rotation axes orthogonal to each other, the output angles of the light beams 12, 22, and 32 output from the light beam scanning device 1 can be changed in two dimensions. Thus, each of the plurality of light beams can generate a scanning region that is a two-dimensional region.

The scanning regions 71, 72, and 73 are arranged in the x axis direction. The scanning region 71 is located between the scanning region 72 and the scanning region 73. The light beam scanning device 1 can expand the scanning region in the x axis direction. The plurality of scanning regions 71, 72, and 73 are more extended than each of the plurality of scanning regions 71, 72, and 73. For example, the plurality of scanning regions 71, 72, and 73 may be arranged in such a manner that an edge of a scanning region in a pair of scanning regions adjacent to each other overlaps only an edge of the other scanning region in the pair of scanning regions adjacent to each other or contacts an edge of the other scanning region in the pair of scanning regions adjacent to each other in the direction (x axis direction) in which the scanning regions 71, 72, and 73 are arranged. The plurality of scanning regions 71, 72, and 73 have a plurality of centers 71c, 72c, and 73c, respectively. Each of the plurality of centers 71c, 72c, and 73c is a center of a corresponding scanning region in the plurality of scanning regions 71, 72, and 73. The positions of the plurality of centers 71c, 72c, and 73c may be different from each other.

In the present embodiment, in the direction (x axis direction) in which the scanning regions 71, 72, and 73 are arranged, one edge of the scanning region 72 overlaps only one edge of the scanning region 71 or contacts one edge of the scanning region 71. In the direction in which the scanning regions 71, 72, and 73 are arranged, one edge of the scanning region 73 overlaps only one edge of the scanning region 71 or contacts one edge of the scanning region 71. The scanning region 71 has a center 71c. The scanning region 72 has a center 72c. The scanning region 73 has a center 73c. The center 72c is shifted from the centers 71c and 73c in the direction in which the scanning regions 71, 72 and 73 are arranged. The center 73c is shifted from the centers 71c and 72c in the direction in which the scanning regions 71, 72, and 73 are arranged. The scanning regions 71, 72, and 73 may not necessarily overlap each other, but may be separated from each other.

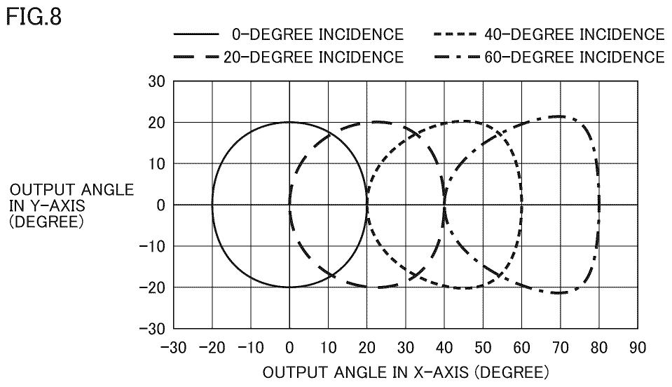

FIG. 8 is a diagram illustrating an example scanning trajectory for each actual incident angle of the light beam incident on the scanning mirror 40 when the scanning mirror 40 is scanned in two dimensions (rotated in two axes) in such a manner that the light beam incident on the scanning mirror 40 with respect to the first normal line thereof at an incident angle of 0 degrees (i.e., in the same direction as the first normal line direction) has an output angle of 20 degrees in all directions (i.e., so as to draw a circle at the position of 20 degrees with respect to the first normal line). FIG. 8 illustrates four examples in which the actual incident angles are 0 degrees, 20 degrees, 40 degrees, and 60 degrees with respect to the first normal line. For all incident angles, the two-dimensional scanning of the scanning mirror 40 is a circular scanning described above.

In the present embodiment, the trajectory shown as 0-degree incidence represents a trajectory drawn by a light beam incident on the scanning mirror 40 with an actual incident angle of 0 degrees with respect to the first normal line in the two-dimensional scanning. Further, the trajectory shown as 20-degree incidence represents a trajectory drawn by a light beam incident on the scanning mirror 40 with an actual incident angle of 20 degrees in the −x axis direction with respect to the first normal line in the two-dimensional scanning. Similarly, the trajectory shown as 40-degree incidence or 60-degree incidence represents a trajectory drawn by a light beam incident on the scanning mirror 40 with an actual incident angle of 40 degrees or 60 degrees in the −x axis direction with respect to the first normal line in the two-dimensional scanning, respectively.

In the case of the 0-degree incidence, the light beam draws a circular scanning trajectory at a position where the output angle is 20 degrees with respect to the first normal line in all directions according to the assumption of the two-dimensional scanning. In FIG. 8, the trajectory drawn by each light beam is illustrated as the output angle with respect to the first normal line in the two orthogonal axial directions of the x axis and the y axis.

On the other hand, in the case of the 20-degree incidence, there is a difference of 20 degrees in the −x axis direction between the incident angle assumed for the two-dimensional scanning and the actual incident angle. Therefore, for example, for a scanning mirror 40 to output a 0-degree incident light beam at 20 degrees in the +x axis direction (a scanning mirror 40 in which the tilt angle of the reflection surface in the xz plane is +10 degrees), the actual incident angle of the light beam incident on the reflection surface of the scanning mirror 40 at 20 degrees (i.e., the incident angle of 20 degrees in the −x axis direction with respect to the first normal line) is 30 degrees in the −x axis direction. As a result, the scanning mirror 40 to output a 0-degree incident light beam at 20 degrees in the +x axis direction functions to output a 20-degree incident light beam at an angle of 40 degrees in the +x axis direction with respect to the first normal line. Further, for example, for a scanning mirror 40 to output a 0-degree incident light beam at 20 degrees in the −x axis direction (a scanning mirror 40 in which the tilt angle of the reflection surface in the xz plane is-10 degrees), the actual incident angle of the light beam incident on the reflection surface of the scanning mirror 40 at 20 degrees is 10 degrees in the −x axis direction. As a result, the scanning mirror 40 to output a 0-degree incident light beam at 20 degrees in the −x axis direction functions to output a 20-degree incident light beam at an angle of 0 degrees in the x axis direction with respect to the first normal line. FIG. 8 illustrates that the scanning trajectory of the 20-degree incident light beam moves in a range of 0 to 40 degrees in the x axis direction. In the figure, it is understood that when a 20-degree incident light beam is output at an angle of about 40 degrees in the +x axis direction, in other words, when the actual incident angle of the light beam incident on the reflection surface of the scanning mirror 40 becomes as large as about 40 degrees, the distortion of the scanning trajectory of the light beam becomes large accordingly.

The same applies to the 40-degree incidence and the 60-degree incidence. For example, in the case of the 40-degree incidence, there is a difference of 40 degrees in the −x axis direction between the incident angle assumed for the two-dimensional scanning and the actual incident angle. Therefore, for example, for a scanning mirror 40 to output a 0-degree incident light beam at 20 degrees in the +x axis direction (a scanning mirror 40 in which the tilt angle of the reflection surface in the xz plane is +10 degrees), the actual incident angle of the light beam incident on the reflection surface of the scanning mirror 40 at 40 degrees (i.e., the incident angle of 40 degrees in the −x axis direction with respect to the first normal line) is 50 degrees in the −x axis direction. As a result, the scanning mirror 40 to output a 0-degree incident light beam at 20 degrees in the +x axis direction functions to output a 40-degree incident light beam at an angle of 60 degrees in the +x axis direction with respect to the first normal line. Further, for example, for a scanning mirror 40 to output a 0-degree incident light beam at 20 degrees in the −x axis direction (a scanning mirror 40 in which the tilt angle of the reflection surface in the xz plane is-10 degrees), the actual incident angle of the light beam incident on the reflection surface of the scanning mirror 40 at 40 degrees is 30 degrees in the −x axis direction. As a result, the scanning mirror 40 to output a 0-degree incident light beam at 20 degrees in the −x axis direction functions to output a 40-degree incident light beam at an angle of 20 degrees in the x axis direction with respect to the first normal line. With reference to FIG. 8, it is understood that when a 40-degree incident light beam is output at an angle of about 60 degrees in the +x axis direction, in other words, when the actual incident angle of the light beam incident on the reflection surface of the scanning mirror 40 becomes as large as about 50 degrees, the distortion of the scanning trajectory of the light beam becomes larger accordingly.

Further, by comparing the 20-degree incidence and the 40-degree incidence, it is understood that as the incident angle of the light beam incident on the scanning mirror 40 in the x axis direction increases, the distortion of the scanning trajectory of the light beam increases. In other words, when the scanning mirror 40 is used to scan a light beam, the scanning trajectory of the light beam 12 incident on the scanning mirror 40 with a relatively small incident angle is less distorted, but the scanning trajectory of the light beam 22 or 32 incident on the scanning mirror 40 with a relatively large incident angle is largely distorted. In order to correct such distortion of the scanning region, the light beam scanning device 1 is provided with a scanning region correction optical member 45.

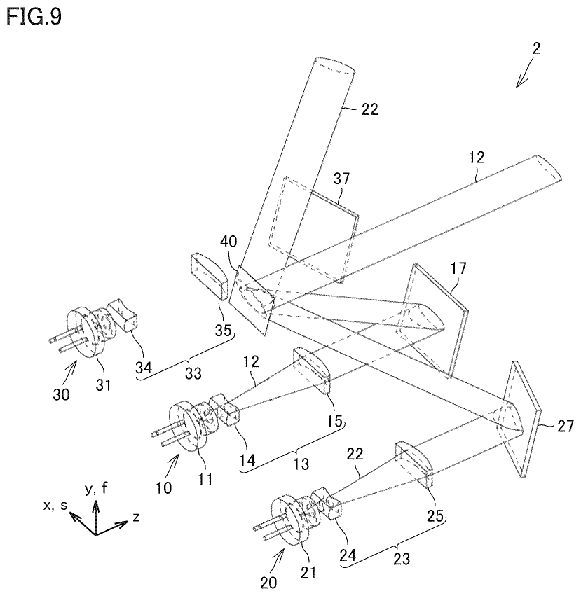

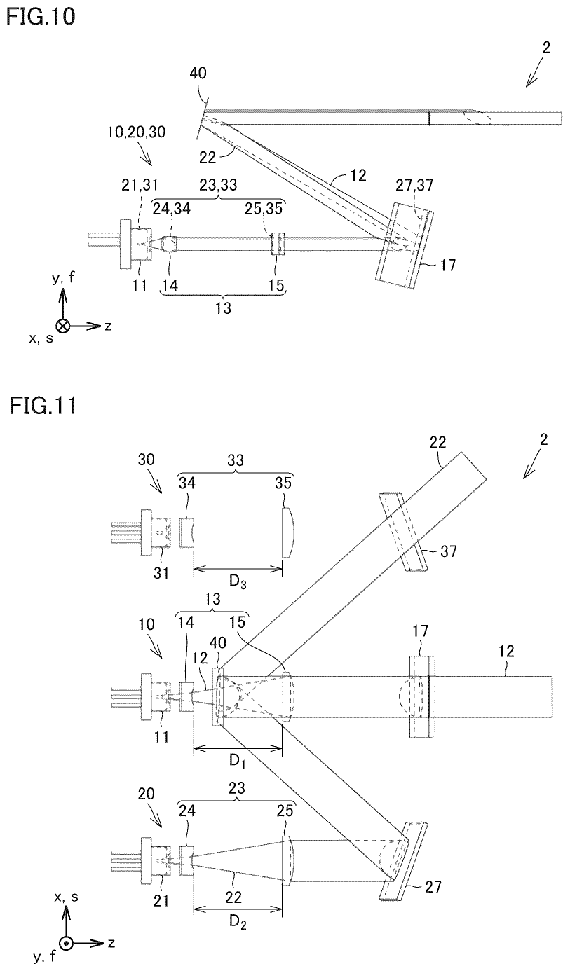

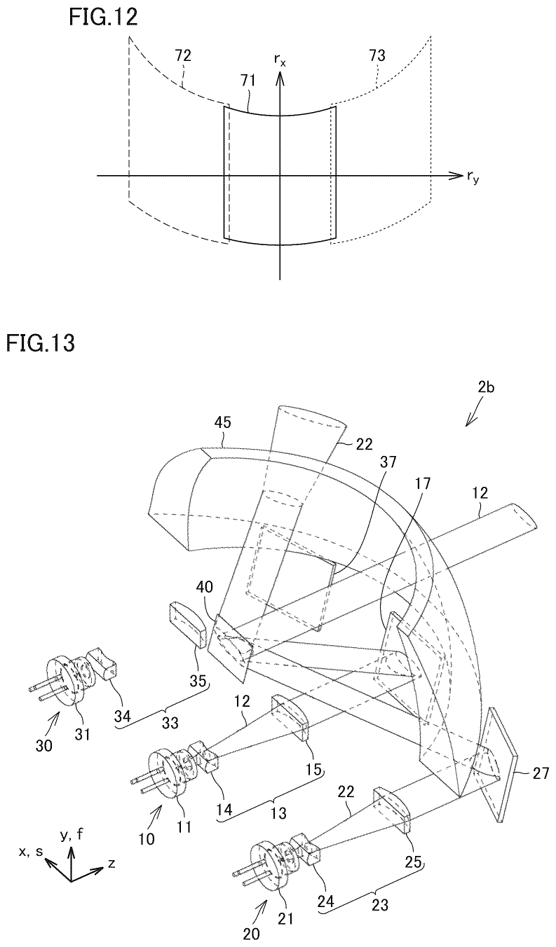

FIGS. 9 to 11 illustrate a light beam scanning device 2 according to a first comparative example. The light beam scanning device 2 according to the first comparative example has a configuration similar to that of the light beam scanning device 1 of the present embodiment, but is mainly different in the following points. The light beam scanning device 2 according to the first comparative example is not provided with a scanning region correction optical member 45. Further, in the light beam scanning device 2 according to the first comparative example, the distance D₁, the distance D₂, and the distance D₃ are equal to each other. Therefore, the beam shaping effect given to the light beams 12, 22, and 32 is equal. In FIGS. 9 to 11, the light beam 32 is not illustrated for simplicity.

FIG. 12 is an explanatory diagram illustrating a scanning region generated by the light beam scanning device 2 according to the first comparative example. Since a rectangular shape is often required as the shape of the scanning region, the light beam scanning device 2 generates the rectangular scanning regions 71, 72, and 73 by swinging the reflection surface of the scanning mirror 40 in two dimensions around the x axis direction and the y axis direction. The greater the incident angle of the light beam incident on the scanning mirror 40 is, the larger the distortion of the shape of the scanning region formed by the light beam will be. Specifically, the incident angle of the light beam 22 incident on the scanning mirror 40 is greater than the incident angle of the light beam 12 incident on the scanning mirror 40. Therefore, as illustrated in FIG. 12, the shape of the scanning region 72 formed by the light beam 22 is more distorted than the shape of the scanning region 71 formed by the light beam 12. The incident angle of the light beam 32 incident on the scanning mirror 40 is greater than the incident angle of the light beam 12 incident on the scanning mirror 40. Therefore, as illustrated in FIG. 12, the shape of the scanning region 73 formed by the light beam 32 is more distorted than the shape of the scanning region 71 formed by the light beam 12.

In FIG. 12, rₓ represents a rotation angle of the scanning mirror 40 about the x axis, and r_{y} represents a rotation angle of the scanning mirror 40 about the y axis. In FIG. 12, the coordinates of the center angle of the scanning region 71 are used as the origin. Since the light beam 22 and the light beam 32 are plane-symmetric with respect to the vertical plane (yz plane) including the optical path of the light beam 12, the scanning regions 72 and 73 are also plane-symmetric with respect to the rₓ axis. As illustrated in FIG. 12, since the incident angle of the light beam 22 incident on the scanning mirror 40 is relatively small, the distortion of the scanning region 71 is small. On the other hand, since the incident angle of the light beam 22 or 32 incident on the scanning mirror 40 is relatively large, the distortion of the scanning region 72 or 73 is large. In addition, similar to the example illustrated in FIG. 8, as the incident angle of the light beam incident on the scanning mirror 40 increases and the rotation angle of the scanning mirror 40 increases, the distortion of the scanning region increases.

The scanning region correction optical member 45 corrects the distortion of the shape of at least one of the scanning regions 71, 72, and 73 formed by the light beams 12, 22, and 32 scanned by the scanning mirror 40. Specifically, the scanning region correction optical member 45 corrects the distortion of the shape of at least two of the scanning regions 71, 72, and 73 (for example, the scanning regions 72 and 73). More specifically, the scanning region correction optical member 45 corrects the distortion of the shape of all of the scanning regions 71, 72, and 73.

The scanning region correction optical member 45 utilizes a refractive effect or a reflective effect to a light beam to deflect the light beam (i.e., to change the traveling direction of the light beam). For example, the shape of a scanning region may be corrected by changing the refractive power given to the light beam according to the incident position of the light beam on the scanning region correction optical member 45. For example, the scanning region correction optical member 45 is an optical member to give different refractive powers to light beams incident on the scanning region correction optical member 45 according to the incident positions of the light beams on the scanning region correction optical member 45. The refractive power of the scanning region correction optical member 45 given to the light beam may be a positive refractive power or a negative refractive power. The scanning region correction optical member 45 may also give a positive refractive power to the light beam at one position of the scanning region correction optical member 45 and give a negative refractive power to the light beam at another position of the scanning region correction optical member 45. The scanning region correction optical member 45 may deflect the light beam such that the light beam incident on the scanning region correction optical member 45 is output in a direction determined according to the incident position of the light beam on the scanning region correction optical member 45.

The scanning region correction optical member 45 is, for example, a lens having a free-form surface (see FIGS. 1 to 3) or a mirror having a free-form surface. The free-form surface of the scanning region correction optical member 45 provides an appropriate deflection effect on the light beam to correct the plurality of scanning regions into an appropriate shape. FIG. 16 illustrates a plurality of scanning regions 71, 72, and 73 generated by the light beam scanning device 1 according to the present embodiment.

For example, the scanning region correction optical member 45 may have a negative refractive power in the slow axis direction of each of the light beams 12, 22, and 32. In this case, the negative refractive power of the scanning region correction optical member 45 to the light beam 22 in the slow axis direction of the light beam 22 is stronger than the negative refractive power of the scanning region correction optical member 45 to the light beam 12 in the slow axis direction of the light beam 12. The negative refractive power of the scanning region correction optical member 45 to the light beam 32 in the slow axis direction of the light beam 32 is stronger than the negative refractive power of the scanning region correction optical member 45 to the light beam 12 in the slow axis direction of the light beam 12. Therefore, the scanning region correction optical member 45 can correct the shape of the scanning region 72 greater than the shape of the scanning region 71, and can correct the shape of the scanning region 73 greater than the shape of the scanning region 71. As illustrated in FIG. 16, the distortion of the shape of each of the scanning regions 71, 72, and 73 is reduced, whereby each of the scanning regions 71, 72, and 73 is corrected to a desired shape such as a substantially rectangular shape.

For example, the scanning region correction optical member 45 may have a positive refractive power in the slow axis direction of each of the light beams 12, 22, and 32. In this case, the positive refractive power of the scanning region correction optical member 45 to the light beam 22 in the slow axis direction of the light beam 22 is stronger than the positive refractive power of the scanning region correction optical member 45 to the light beam 12 in the slow axis direction of the light beam 12. The positive refractive power of the scanning region correction optical member 45 to the light beam 32 in the slow axis direction of the light beam 32 is stronger than the positive refractive power of the scanning region correction optical member 45 to the light beam 12 in the slow axis direction of the light beam 12. Therefore, the scanning region correction optical member 45 can correct the shape of the scanning region 72 greater than the shape of the scanning region 71, and can correct the shape of the scanning region 73 greater than the shape of the scanning region 71. As illustrated in FIG. 16, the distortion of the shape of each of the scanning regions 71, 72, and 73 is reduced, whereby each of the scanning regions 71, 72, and 73 is corrected to a desired shape such as a substantially rectangular shape.

The scanning region correction optical member 45 may be designed, for example, to produce little optical effect to a light beam (for example, the light beam 12) incident on the scanning mirror 40 with a relatively small incident angle, and to produce a large optical effect to a light beam (for example, the light beam 22 or 32) incident on the scanning mirror 40 with a relatively large incident angle. This optical effect may be a negative refractive power, a positive refractive power, or a mixture of the negative refractive power and the positive refractive power (for example, a negative refractive power is given to a light beam incident at one position of the scanning region correction optical member 45, and a positive refractive power is given to a light beam incident at another position of the scanning region correction optical member 45).

Along with the deflection effect of the scanning region correction optical member 45, the scanning region correction optical member 45 may change the spread angle of a light beam to reduce the parallelism of the light beam. In other words, the scanning region correction optical member 45 may provide a positive effect such as a deflection effect to correct the distortion of the scanning region, and may also provide a negative effect to the beam quality such as a decrease in the parallelism of the light beam. As an example, even though the beam shaper collimates the light beam, the scanning region correction optical member 45 converts the light beam into a divergent light beam or a convergent light beam to reduce the parallelism of the light beam. Whether the light beam is a divergent light beam or a convergent light beam immediately after output from the scanning region correction optical member 45, the light beam becomes divergent with respect to an object far away from the light beam scanning device 1. Therefore, when the parallelism of the light beam output from the scanning region correction optical member 45 is small, the object far away from the light beam scanning device 1 will be irradiated with a light beam of a low brightness, which reduces the accuracy of measuring the position of the object.

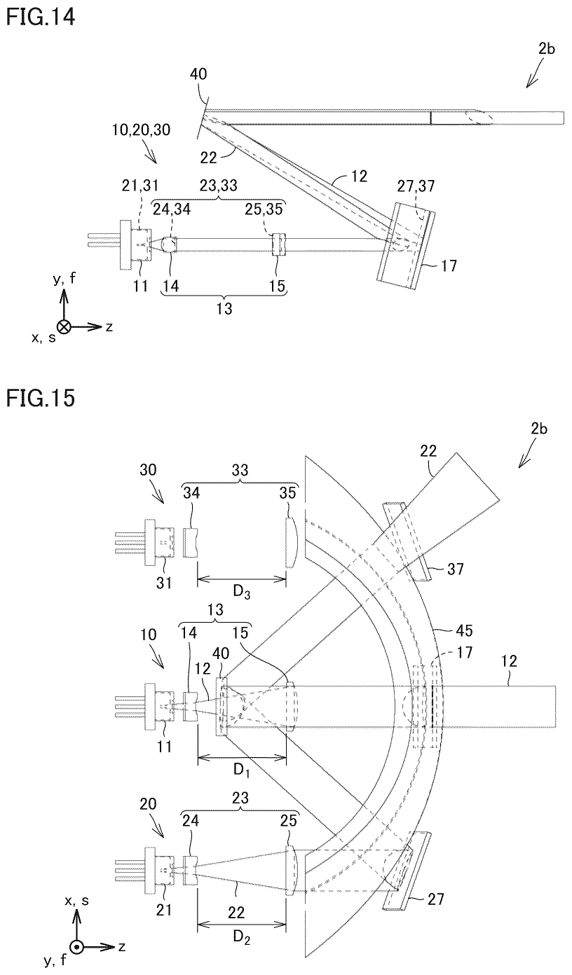

On the other hand, when the refractive power given to the light beam by the scanning region correction optical member 45 is different according to the incident position of the light beam on the scanning region correction optical member 45, the amount of change in the spread angle of the light beam output from the scanning region correction optical member 45 by the scanning region correction optical member 45 is different according to the incident position of the light beam on the scanning region correction optical member 45 and the light beam diameter of the light beam incident on the scanning region correction optical member 45. In the present embodiment, the parallelism of the light beam output from the scanning region correction optical member 45 is improved by adjusting the distance between the lenses in the beam shaper while maintaining the effect of correcting the distortion of the scanning region by the scanning region correction optical member 45. With reference to a light beam scanning device 2b according to a second comparative example of FIGS. 13 to 15, an example of adjusting the distance between the front lens and the rear lens in each of the plurality of beam shapers included in the light beam scanning device 1 of the present embodiment will be described. In FIGS. 13 to 15, the light beam 32 is not illustrated for simplicity.

As illustrated in FIGS. 13 to 15, the light beam scanning device 2b according to the second comparative example further includes a scanning region correction optical member 45 as compared with the light beam scanning device 2 according to the first comparative example. However, in the light beam scanning device 2b according to the second comparative example, the distance D₁, the distance D₂, and the distance D₃ are equal to each other, which is the same as the light beam scanning device 2 according to the first comparative example. The other components are the same as those of the light beam scanning device 1 of the present embodiment.

In order to increase the light intensity of each of the light beams 12, 22, and 32, a light source having a high output power, such as a multi-mode diode laser, may be employed as the light source 11, 21, or 31. In such a light source, the width W₁ (see FIG. 4) of the emitter 60 of each of the light sources 11, 21, and 31 in the slow axis direction of each of the light beams 12, 22, and 32 is greater than the width W₂ (see FIG. 4) of the emitter 60 of each of the light sources 11, 21, and 31 in the fast axis direction of each of the light beams 12, 22, and 32.

FIG. 17 is a diagram illustrating a relationship between a light emitting point width W, a focal length f of a lens optical system, and a spread angle θ of a light beam passing through the lens optical system. In general, the spread angle θ of the light beam emitted from the light emitting point and passing through the lens optical system is defined by the following equation (1). The greater the light emitting point width W is, the larger the spread angle θ of the light beam passing through the lens optical system will be. The longer the focal length f of the lens optical system is, the smaller the spread angle θ of the light beam passing through the lens optical system will be.

$$θ ≅ W / f \qquad ( 1 )$$

In the present disclosure, the light emitting point width W corresponds to the width of the emitter of a light source. The lens optical system corresponds to a composite lens constituted by a combination of a front lens and a rear lens included in the beam shaper. The spread angle θ of the light beam corresponds to the spread angle of each of the light beams 12, 22, and 32 output from the beam shaper. Therefore, when the focal length of the beam shaper 13 (the composite lens) in the slow axis direction of the light beam 12 is equal to the focal length of the beam shaper 13 (the composite lens) in the fast axis direction of the light beam 12, the spread angle of the light beam 12 passing through the beam shaper 13 in the slow axis direction is greater than the spread angle of the light beam 12 passing through the beam shaper 13 in the fast axis direction. The same applies to the light beams 22 and 32.

With reference to the equation (1), when the width W₂ of the emitter 60 in the fast axis direction (hereinafter also referred to as “light emitting point width Wf”) is sufficiently small so that the emitter 60 may be regarded as an optical point in the fast axis direction, the spread angle of each light beam in the fast axis direction is sufficiently small even if the focal length of each beam shaper (the composite focal length of the front lens and the rear lens) in the fast axis direction is short. Therefore, the front lens may be mainly used to perform the beam shaping in each beam shaper in the fast axis direction, and the focal length of the front lens in the fast axis direction may be shortened in each beam shaper (in other words, the positive refractive power of the front lens may be increased in each beam shaper). Thus, it is possible to sufficiently reduce the spread angle of each light beam in the fast axis direction, and it is also possible to reduce the light beam diameter of each light beam in the fast axis direction.

On the other hand, if the width W₁ of the emitter 60 in the slow axis direction (hereinafter also referred to as “light emitting point width Ws”) is sufficiently large, the emitter 60 cannot be regarded as an optical point in the slow axis direction. Thus, with reference to the equation (1), the spread angle of each light beam in the slow axis direction is reduced by increasing the focal length of each beam shaper in the slow axis direction (the composite focal length of the front lens and the rear lens). However, as the focal length of each beam shaper in the slow axis direction becomes greater, the light beam diameter of each light beam output from each beam shaper becomes greater. Therefore, in the slow axis direction, the negative effect of the scanning region correction optical member 45 (for example, the curvature effect of the scanning region correction optical member 45 that reduces the parallelism of the light beam) becomes greater.

Based on the relationship between the parallelism of the light beam and the light beam diameter of the light beam, the beam shaper is designed as follows. Specifically, the beam shaper is designed to give a positive refractive power only to the front lens in the fast axis direction so as to shorten the focal length F1f of the front lens. Therefore, in the fast axis direction, the parallelism of each light beam in the scanning region correction optical member 45 is high, and the light beam diameter of each light beam in the scanning region correction optical member 45 is small. Not only the light beam 12 but also the light beams 22 and 32 incident on the scanning mirror 40 with a large incident angle are less susceptible to the curvature effect of the scanning region correction optical member 45. Further, it is no longer necessary to adjust the distance between the light source and the front lens for each light source module.

On the other hand, in the slow axis direction, the light beam diameter of each light beam in the scanning region correction optical member 45 is large. Further, each of the scanning regions 72 and 73 is greatly corrected than the scanning region 71 by the scanning region correction optical member 45. Therefore, in the slow axis direction, the light beams 22 and 32 incident on the scanning mirror 40 with a larger incident angle are subject to a larger negative effect of the scanning region correction optical member 45 (a larger curvature effect of the scanning region correction optical member 45) than the light beam 12.

Therefore, in the present embodiment, the position of the rear lens with respect to the front lens is adjusted in accordance with the intensity of the negative effect of the scanning region correction optical member 45 (the curvature effect of the scanning region correction optical member 45). The focal length of the light beam output from the beam shaper in the slow axis direction is changed according to the intensity of the negative effect of the scanning region correction optical member 45 so as to change the spread angle of the light beam output from the beam shaper in the slow axis direction. At least a part of the negative effect of the scanning region correction optical member 45 is offset by the spread angle of the light beam output from the beam shaper in the slow axis direction. Thus, the parallelism of each light beam in the scanning region correction optical member 45 is improved. Thereby, the quality of the light beam output from the scanning region correction optical member 45 can be improved. Note that each beam shaper may be configured to reduce the light beam diameter of each of the plurality of light beams incident on the scanning region correction optical member 45 in the fast axis direction smaller than the light beam diameter in the slow axis direction.

In the example of the present embodiment illustrated in FIGS. 1 to 3, the scanning region correction optical member 45 gives a negative refractive power in the slow axis direction to the light beams 22 and 32, each of which is incident on the scanning mirror 40 with a greater incident angle than the light beam 12. In this case, the distance between the front lens and the rear lens in each of the beam shapers 23 and 33 is made greater than the distance between the front lens and the rear lens in the beam shaper 13. In other words, the rear lenses 15, 25 and 35 are disposed with respect to the front lenses 14, 24 and 34, respectively, so that the distance D₁ is smaller than the distance D₂ and the distance D₁ is smaller than the distance D₃. For example, the curvature effect (negative refractive power) of the scanning region correction optical member 45 may be corrected by intentionally shifting the rear lens from the focal position (the position where the beam shaper focuses the object side focal point to the light emitting point) to the output side according to the amount of the curvature effect. Thus, the beam shaper 23 or 33 outputs a light beam converging in the slow axis direction. Even when a light beam converging in the slow axis direction is output from the beam shaper 23 or 33, the negative refractive power of the scanning region correction optical member 45 in the slow axis direction causes the scanning region correction optical member 45 to output a substantially parallel light beam.

In the example of the present embodiment illustrated in FIGS. 1 to 3, the light beams 22 and 32 converging in the x axis direction, which coincides with the slow axis direction, are output from the beam shapers 23 and 33, respectively, and the light beam 12 parallel to the x axis direction is output from the beam shaper 13. The substantially parallel light beams 12, 22, and 32 are output from the scanning region correction optical member 45. On the other hand, in the light beam scanning device 2b according to the second comparative example illustrated in FIGS. 13 to 15, the light beams 12 and 22 substantially parallel to each other in the x axis direction, which coincides with the slow axis direction, are output from the beam shapers 13 and 23, respectively. The substantially parallel light beam 12 and the divergent light beam 22 are output from the scanning region correction optical member 45. Although the light beam 32 is not illustrated in FIGS. 13 to 15, similar to the light beam 22, the light beam 32 is output from the scanning region correction optical member 45 as a divergent light beam.

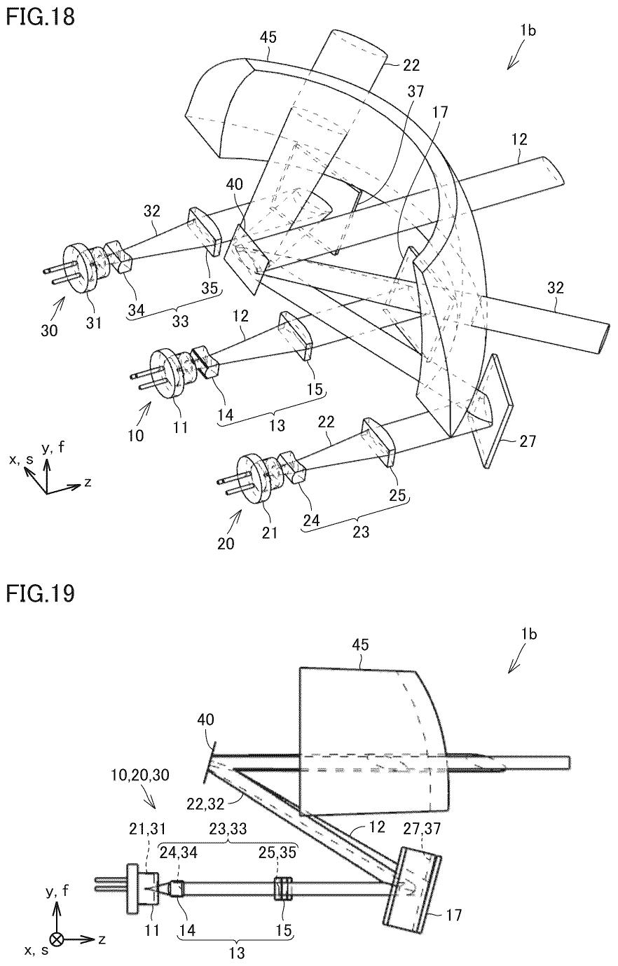

In the light beam scanning device 1b which is another example of the present embodiment illustrated in FIGS. 18 to 20, the scanning region correction optical member 45 gives a positive refractive power in the slow axis direction to the light beam 22 or 32, each of which is incident on the scanning mirror 40 with a greater incident angle than the light beam 12. In this case, the distance between the front lens and the rear lens in the beam shapers 23 and 33 is made smaller than the distance between the front lens and the rear lens in the beam shaper 13. In other words, the rear lenses 15, 25 and 35 are disposed with respect to the front lenses 14, 24 and 34, respectively, so that the distance D₁ is greater the distance D₂ and the distance D₁ is greater the distance D₃. For example, the curvature effect (negative refractive power) of the scanning region correction optical member 45 may be corrected by intentionally shifting the rear lens from the focal position to the incident side according to the amount of the curvature effect. Thus, the beam shaper 23 or 33 outputs a light beam diverging in the slow axis direction. Even when the light beam diverging in the slow axis direction is output from the beam shaper 23 or 33, the positive refractive power of the scanning region correction optical member 45 in the slow axis direction causes the scanning region correction optical member 45 to output a substantially parallel light beam.

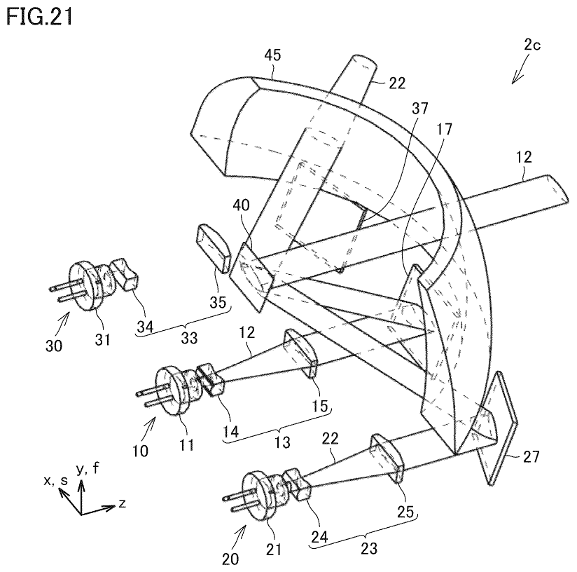

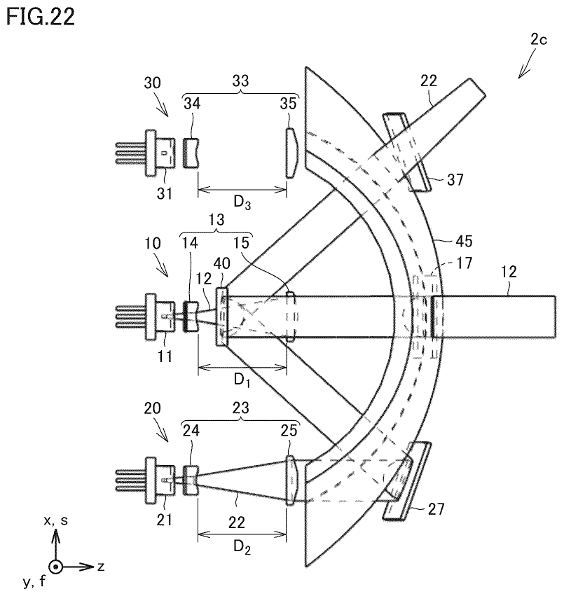

In another example of the present embodiment illustrated in FIGS. 18 to 20, the light beams 22 and 32 diverging in the x axis direction, which coincides with the slow axis direction, are output from the beam shapers 23 and 33, respectively, and the light beam 12 parallel to the x axis direction is output from the beam shaper 13. The substantially parallel light beams 12, 22, and 32 are output from the scanning region correction optical member 45. On the other hand, in the light beam scanning device 2c according to the third comparative example illustrated in FIGS. 21 and 22, the distances D₁, D₂, and D₃ are equal to each other, and the light beams 12, 22, and 32 substantially parallel to each other in the x axis direction, which coincides with the slow axis direction, are output from the beam shapers 13, 23, and 33, respectively. The substantially parallel light beam 12 and the convergent light beam 22 are output from the scanning region correction optical member 45. Although the light beam 32 is not illustrated in FIGS. 21 and 22, similar to the light beam 22, the light beam 32 is output from the scanning region correction optical member 45 as a convergent light beam.

In the present embodiment, since the light beam diameter of the light beam in the fast axis direction is small, the effect of the scanning region correction optical member 45 on the light beam in the fast axis direction can be ignored.

It is not necessary to collimate all of the light beams output from the scanning region correction optical member 45. The parallelism (spread angle) of each light beam output from the scanning region correction optical member 45 may be appropriately adjusted according to the distance from the light beam scanning device 1 or 1b to the object to be scanned, the required quality of the light beam and the like.

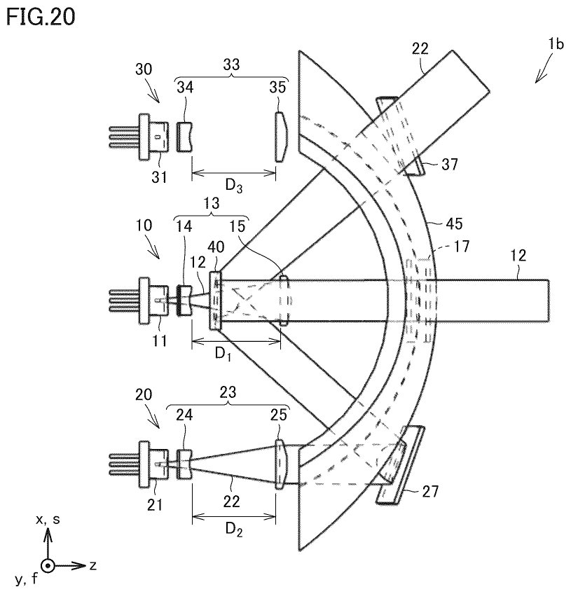

In the light beam scanning device 2b according to the second comparative example (see FIGS. 13 to 15) and the light beam scanning device 2c according to the third comparative example (see FIGS. 20 and 21), since the distance between the front lens and the rear lens in each beam shaper is equal, the parallelism (spread angle) of the light beam incident on the scanning region correction optical member 45 is equal to each other. The refractive power of a peripheral portion of the scanning region correction optical member 45 is stronger than the refractive power of a central portion of the scanning region correction optical member 45. Therefore, when the distance between the front lens and the rear lens of each beam shaper is set such that the light beam 12 output from the scanning region correction optical member 45 becomes a substantially parallel light beam, each of the light beams 22 and 32 output from the scanning region correction optical member 45 diverges or converges in the slow axis direction. On the other hand, when the distance between the front lens and the rear lens in each beam shaper is set such that the light beams 22 and 32 output from the scanning region correction optical member 45 become substantially parallel light beams, the light beam 12 output from the scanning region correction optical member 45 diverges or converges.

On the other hand, in the light beam scanning device 1 or 1b according to the present embodiment, the distance (the distance D₁, D₂, or D₃ illustrated in FIG. 3) between the front lens and the rear lens in each beam shaper is changed according to the optical effect given to the light beam by the scanning region correction optical member 45. Therefore, it is possible to improve the parallelism of each light beam output from the light beam scanning device 1 or 1b. Thereby, the light beam scanning device 1 or 1b can output high-quality light beams.

### Modifications

The light source module 30 and the reflective mirror 37 and the light source module 20 and the reflective mirror 27 may be asymmetrically arranged with respect to a vertical plane including the optical path of the light beam 12. For example, the incident angle of the light beam 32 incident on the scanning mirror 40 may be different from the incident angle of the light beam 22 incident on the scanning mirror 40, and the distance D₃ may be different from the distance D₂. For example, when the incident angle of the light beam 32 incident on the scanning mirror 40 is greater than the incident angle of the light beam 22 incident on the scanning mirror 40 and the scanning region correction optical member 45 gives a larger negative refractive power to the light beam 32 incident on the scanning mirror 40 with a greater incident angle, the distance D₃ may be greater than the distance D₂. Further, for example, when the incident angle of the light beam 32 incident on the scanning mirror 40 is greater than the incident angle of the light beam 22 incident on the scanning mirror 40 and the scanning region correction optical member 45 gives a larger positive refractive power to the light beam 32 incident on the scanning mirror 40 with a greater incident angle, the distance D₃ may be smaller than the distance D₂.

The fast axis direction of the light beam 32 may be parallel to the fast axis direction of the light beam 22, or may not be parallel to the fast axis direction of the light beam 12. The slow axis direction of the light beam 32 may be parallel to the slow axis direction of the light beam 22, or may not be parallel to the slow axis direction of the light beam 22.

The number of the light source modules 10, 20 and 30 or the number of the reflection mirrors 17, 27 and 37 is not limited to three.

Effects of the light beam scanning device 1, 1b according to the present embodiment will be described.

The light beam scanning device 1, 1b according to the present embodiment includes a plurality of light sources (for example, the light sources 11, 21, and 31), a plurality of beam shapers (for example, the beam shapers 13, 23, and 33), a scanning mirror 40, and a scanning region correction optical member 45. The plurality of light sources emit a plurality of light beams (for example, the light beams 12, 22, and 32). Each of the plurality of light beams is emitted from a corresponding light source of the plurality of light sources and has a larger light beam diameter in the fast axis direction than in the slow axis direction. Each of the plurality of beam shapers is provided for a corresponding light source of the plurality of light sources, and shapes a light beam emitted from the corresponding light source. The scanning mirror 40 scans a plurality of light beams shaped by the plurality of beam shapers. The scanning region correction optical member 45 corrects at least one of a plurality of scanning regions formed by the plurality of light beams scanned by the scanning mirror 40. Each of the plurality of beam shapers includes a first lens (for example, the front lens 14, 24, 34) and a second lens (for example, the rear lens 15, 25, 35). The first lens is disposed closer to a corresponding light source of the plurality of light sources than the second lens. Each of the plurality of beam shapers gives a positive refractive power to a corresponding light source of the plurality of light beams in both the slow axis direction and the fast axis direction. Each of the beam shapers has a focal length Ff in the fast axis direction and a focal length Fs in the slow axis direction greater than the focal length Fs. In at least one direction, an incident angle θ1 of a first light beam (for example, the light beam 12), which is one of the plurality of light beams, on the scanning mirror 40 when the scanning mirror 40 is positioned in the center of the rotation range of the scanning mirror 40 is different from an incident angle θ2 of a second light beam (for example, the light beam 22), which is one of the plurality of light beams, on the scanning mirror 40 when the scanning mirror 40 is positioned in the center of the rotation range of the scanning mirror 40. A distance D₁ between a first lens (for example, the front lens 14) and a second lens (for example, the rear lens 15) in a first beam shaper (for example, the beam shaper 13) which is one of the plurality of beam shapers and shapes a first light beam is different from a distance D₂ between a first lens (for example, the front lens 24) and a second lens (for example, the rear lens 25) in a second beam shaper (for example, the beam shaper 23) which is one of the plurality of beam shapers and shapes a second light beam.

The light beam scanning device 1, 1b according to the present embodiment includes a scanning region correction optical member 45. Therefore, the light beam scanning device 1, 1b can correct the distortion or the like of a scanning region (for example, the scanning region 71, 72, 73) caused by the difference in the incident angle of the light beam incident on the scanning mirror 40. The beam shaper includes a first lens (for example, the front lens 14, 24, 34) and a second lens (for example, the rear lens 15, 25, 35). The distance between the first lens and the second lens is made different between two beam shapers (for example, the beam shapers 13 and 23) that shape two light beams (for example, the light beams 12 and 22) incident on the scanning mirror 40 with different incident angles. Therefore, the parallelism of the light beam output from the scanning region correction optical member 45 such as the quality of the light beam output from the scanning region correction optical member 45 is improved.

In other words, in the case where the light beam scanning device 1, 1b having a plurality of scanning regions is provided with a scanning region correction optical member 45 for correcting distortion or the like of a scanning region, by varying the distance between lenses in different beam shapers provided for at least two light beams incident on the scanning mirror 40 with different incident angles, it is possible to obtain the effect of correcting the scanning region caused by the deflection of the light beams, which is the first effect of the scanning region correction optical member 45, and it is also possible to reduce the effect (the divergence or convergence of the outputting light) by varying the divergence angle of the outputting light, which is the second effect associated with the first effect of the scanning region correction optical member 45.

In the light beam scanning device 1 according to the present embodiment, the incident angle θ2 is greater than the incident angle θ1. The scanning region correction optical member 45 gives a negative refractive power to the second light beam in the slow axis direction. The distance D₂ is greater than the distance D₁.

Therefore, the light beam scanning device 1 can correct the distortion or the like of the scanning region (for example, the scanning region 71, 72, 73) and can improve the quality of the light beam output from the scanning region correction optical member 45.

In the light beam scanning device 1b according to the present embodiment, the incident angle θ2 is greater than the incident angle θ1. The scanning region correction optical member 45 gives a positive refractive power to the second light beam in the slow axis direction. The distance D₂ is smaller than the distance D₁.

Therefore, the light beam scanning device 1b can correct the distortion or the like of the scanning region (for example, the scanning region 71, 72, 73) and can improve the quality of the light beam output from the scanning region correction optical member 45.

In the light beam scanning device 1, 1b according to the present embodiment, the first lens (for example, the front lens 14, 24, 34) has a positive refractive power in the fast axis direction. The second lens (for example, the rear lens 15, 25, 35) has a positive refractive power in the slow axis direction. A focal length F2s of the second lens in the slow axis direction is greater than a focal length F1f of the first lens in the fast axis direction.

Therefore, the parallelism of the light beam in the slow axis direction is improved. The light beam diameter of the light beam in the fast axis direction in the scanning region correction optical member 45 is smaller than the light beam diameter of the light beam in the slow axis direction in the scanning region correction optical member 45. The decrease in the parallelism of the light beam in the fast axis direction caused by the scanning region correction optical member 45 can be ignored. Thereby, it is possible to improve the quality of the light beam output from the scanning region correction optical member 45.

In the light beam scanning device 1, 1b according to the present embodiment, the second lens (for example, the rear lens 15, 25, 35) has a zero refractive power in the fast axis direction.

Therefore, it is possible to adjust the distance (for example, the distance D₁, D₂, D₃) between the first lens (for example, the front lens 14, 24, 34) and the second lens (for example, the rear lens 15, 25, 35) without affecting the parallelism of the light beam in the fast axis direction by moving the second lens. The parallelism of the light beam caused by the scanning region correction optical member 45 is improved. Thereby, it is possible to improve the quality of the light beam output from the scanning region correction optical member 45.

In the light beam scanning device 1, 1b according to the present embodiment, the first lens (for example, the front lens 14, 24, 34) has a negative refractive power in the slow axis direction.

Therefore, the beam shaper (for example, the beam shaper 13, 23, 33) can be downsized. Thereby, the light beam scanning device 1, 1b can be downsized.

In the light beam scanning device 1, 1b according to the present embodiment, a divergence angle of the light beam incident on the first lens (for example, the front lens 14, 24, 34) in the slow axis direction is smaller than a divergence angle of the light beam incident on the first lens in the fast axis direction. A divergence angle of the light beam incident on the second lens (for example, the rear lens 15, 25, 35) in the slow axis direction is greater than a divergence angle of the light beam incident on the second lens in the fast axis direction.

Therefore, it is easier to obtain the effects such as correcting the distortion or the like of the scanning region (for example, the scanning region 71, 72, 73) and improving the quality of the light beam output from the scanning region correction optical member 45.

In the light beam scanning device 1, 1b according to the present embodiment, each of a plurality of light sources (for example, the light sources 11, 21, 31) is a multi-mode laser diode. An emitter width of the multi-mode laser diode in the slow axis direction is greater than an emitter width of the multi-mode laser diode in the fast axis direction.

Therefore, it is possible to increase the power of the light beam (for example, the light beam 12, 22, 32). Thereby, it is possible for the light beam scanning device 1, 1b to scan an object at a further distant position.

In the light beam scanning device 1, 1b according to the present embodiment, each of the plurality of light beams incident on the scanning region correction optical member 45 has a light beam diameter in the fast axis direction and a light beam diameter in the slow axis direction, and the light beam diameter in the fast axis direction is smaller than the light beam diameter in the slow axis direction.

Therefore, a decrease in the parallelism of the light beam caused by the scanning region correction optical member 45 in the fast axis direction can be ignored. Thereby, it is possible to improve the quality of the light beam output from the scanning region correction optical member 45.

In the light beam scanning device 1, 1b according to the present embodiment, the scanning region correction optical member 45 is a lens having a free-form surface or a mirror having a free-form surface.

The free-form surface of the scanning region correction optical member 45 can provide an appropriate deflection effect on the light beam to correct a plurality of scanning regions into an appropriate shape.

In the light beam scanning device 1, 1b according to the present embodiment, an amount of change in a spread angle given to the first light beam by the scanning region correction optical member 45 is different from an amount of change in a spread angle given to the second light beam by the scanning region correction optical member 45.

Therefore, the parallelism of the light beam output from the scanning region correction optical member 45 is improved. Thereby, it is possible to improve the quality of the light beam output from the scanning region correction optical member 45.

In the light beam scanning device 1, 1b according to the present embodiment, the plurality of light sources include a first light source (for example, the light source 11), a second light source (for example, the light source 21), and a third light source (for example, the light source 31). An incident angle of the light beam (for example, the light beam 12) emitted from the first light source to the scanning mirror 40 is different from at least one of an incident angle of the light beam (for example, the light beam 22) emitted from the second light source to the scanning mirror 40 or an incident angle of the light beam (for example, the light beam 32) emitted from the third light source to the scanning mirror 40.

Therefore, the parallelism of the light beam output from the scanning region correction optical member 45 caused by the difference in the incident angle of the light beam incident on the scanning mirror 40 is improved. Thereby, it is possible to improve the quality of the light beam output from the scanning region correction optical member 45.

In the light beam scanning device 1, 1b according to the present embodiment, the at least one direction is one direction perpendicular to a rotation axis of the scanning mirror, a direction in which a difference between the incident angles of the plurality of light beams on the scanning mirror is the largest, or a longitudinal direction of the plurality of scanning regions.

By selecting a direction in which the distortion of the scanning region is likely to be greater, it is easier to obtain the effects such as correcting the distortion or the like of the scanning region (for example, the scanning region 71, 72, 73) and improving the quality of the light beam output from the scanning region correction optical member 45.

In the light beam scanning device 1, 1b according to the present embodiment, the plurality of scanning regions are more extended than each of the plurality of scanning regions.

Therefore, the light beam scanning device 1, 1b can scan a wider region.

In the light beam scanning device 1, 1b according to the present embodiment, the plurality of scanning regions have a plurality of centers. Each of the plurality of centers is a center of a corresponding scanning region among the plurality of scanning regions. The plurality of centers are different from each other in position.

Therefore, the light beam scanning device 1, 1b can scan a wider region.

### Second Embodiment

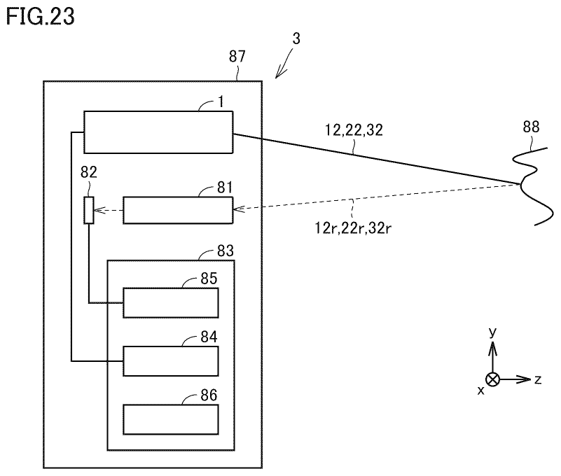

A distance measuring device 3 according to a second embodiment will be described with reference to FIG. 23. FIG. 23 is a diagram schematically illustrating an example of the distance measuring device 3 according to the third embodiment. As illustrated in FIG. 23, the distance measuring device 3 includes a light beam scanning device 1 according to the first embodiment, a light receiving optical system 81, a light receiving unit 82, a computer 83, and a housing 87.

The light receiving optical system 81 directs, to the light receiving unit 82, return light beams 12r, 22r and 32r generated when the light beams 12, 22, and 32 are reflected or scattered by an object 88, respectively. The light receiving optical system 81 includes, for example, a condenser lens. The light receiving unit 82 receives the return light beams 12r, 22r, and 32r. The light receiving unit 82 is, for example, a photodiode such as an avalanche photodiode or a single-photon avalanche photodiode.

The computer 83 includes a controller 84, a calculation unit 85, and a storage unit 86 such as a ROM or a hard disk. The controller 84 and the calculation unit 85 may be a processor such as a CPU (Central Processing Unit), a GPU (Graphics Processing Unit), or a FPGA (Field-Programmable Gate Array) included in the computer 83.

The controller 84 is communicatively connected to the light sources 11, 21 and 31, the scanning mirror 40, and the light receiving unit 82. The controller 84 controls the distance measuring device 3.

Specifically, the controller 84 controls the light sources 11, 21, and 31 to control a timing at which the light sources 11, 21, and 31 emit the pulsed light beams 12, 22, and 32, respectively. The controller 84 receives a first timing at which the light sources 11, 21, and 31 emit the pulsed light beams 12, 22, and 32, respectively. The first timing includes a timing at which the light source 11 emits the light beam 12, a timing at which the light source 21 emits the light beam 22, and a timing at which the light source 31 emits the light beam 32.

The controller 84 controls the scanning mirror 40. The controller 84 receives a tilt angle of the scanning mirror 40 (for example, an angle of the reflective surface of the scanning mirror 40 relative to the normal line). The controller 84 receives, from the light receiving unit 82, a signal corresponding to a light intensity of each of the return light beams 12r, 22r and 32r received by the light receiving unit 82. The controller 84 receives a second timing at which the light receiving unit 82 receives the return light beams 12r, 22r, and 32r, respectively. The second timing includes a timing at which the light receiving unit 82 receives the return light beam 12r, a timing at which the light receiving unit 82 receives the return light beam 22r, and a timing at which the light receiving unit 82 receives the return light beam 32r.

The calculation unit 85 calculates the direction and distance of the object 88 based on the emission direction of each of the light beam 12, 22, and 32, the first timing at which the light sources 11, 21, and 31 emit the light beams 12, 22, and 32, respectively, and the second timing at which the light receiving unit 82 receives the return light beams 12r, 22r, and 32r, respectively.

Specifically, the calculation unit 85 calculates the emission direction of each of the light beams 12, 22, and 32 from the tilt angle of the scanning mirror 40 which is received by the controller 84 and the position of each of the light sources 11, 21, and 31 with respect to the scanning mirror 40 which is stored in the storage unit 86. The calculation unit 85 receives, from the controller 84, the first timing at which the light sources 11, 21, and 31 emit the light beams 12, 22, and 32, respectively. The calculation unit 85 receives, from the controller 84, the second timing at which the light receiving unit 82 receives the return light beams 12r, 22r, and 32r, respectively.

The calculation unit 85 calculates the distance from the distance measuring device 3 to the object 88 and the direction of the object 88 with respect to the distance measuring device 3 based on the emission direction of each of the light beams 12, 22, and 32, the first timing and the second timing. The calculation unit 85 generates a distance image of the object 88 including the distance from the distance measuring device 3 to the object 88 and the direction of the object 88 with respect to the distance measuring device 3. The calculation unit 85 outputs the distance image of the object 88 to a display device (not shown) communicatively connected to the storage unit 86 or the computer 83. The display device displays the distance image of the object 88.

The housing 87 houses the light beam scanning device 1, the light receiving optical system 81, the light receiving unit 82, and the computer 83. The housing 87 is provided with a transparent window (not shown) for transmitting the light beams 12, 22, and 32 and the return light beams 12r, 22r, and 32r. The computer 83 may be disposed outside the housing 87.

The distance measuring device 3 may include a light beam scanning device 1b to replace the light beam scanning device 1 according to the first embodiment.

The distance measuring device 3 according to the present embodiment exhibits the following effects in addition to the effect of the light beam scanning device 1, 1b according to the first embodiment.

The distance measuring device 3 according to the present embodiment includes a light beam scanning device 1 or a light beam scanning device 1b, a light receiving unit 82, and a calculation unit 85. The light receiving unit 82 receives a first return light beam (for example, a return light beam 12r) generated when the first light beam (for example, the light beam 12) is reflected or scattered by the object 88 and a second return light beam (for example, a return light beam 22r) generated when the second light beam (for example, the light beam 22) is reflected or scattered by the object 88. The calculation unit 85 calculates the direction and distance of the object 88 based on the first emission direction of the first light beam, the second emission direction of the second light beam, the first emission timing at which the first light source (for example, the light source 11) emits the first light beam, the second emission timing at which the second light source (for example, the light source 21) emits the second light beam, the first reception timing at which the light receiving unit 82 receives the first return light beam, and the second reception timing at which the light receiving unit 82 receives the second return light beam.

The distance measuring device 3 includes a light beam scanning device 1 or a light beam scanning device 1b. Thus, the first light beam (for example, the light beam 12) and the second light beam (for example, the light beam 22) can be used to measure the position of the object 88 with improved accuracy.

It should be understood that the first and second embodiments disclosed herein are illustrative and not restrictive in all respects. The scope of the present disclosure is defined not by the above description but by the terms of the claims, and is intended to include all changes within the meaning and scope equivalent to the claims.

### REFERENCE SIGNS LIST

1, 1b, 2, 2b, 2c: light beam scanning device; 3: distance measuring device; 10, 20, 30: light source module; 11, 21, 31: light source; 12, 22, 32: light beam; 12r, 22r, 32r: return light beam; 13, 23, 33: beam shaper; 14, 24, 34: front lens; 15, 25, 35: rear lens; 17, 27, 37: reflection mirror; 40: scanning mirror; 45: scanning region correction optical member; 51: substrate; 52, 54: cladding layer; 53: active layer; 55: ridge portion; 56, 57: electrode; 59: insulating layer; 60: emitter (light emitting point); 71, 72, 73: scanning region; 71c, 72c, 73c: center; 81: light receiving optical system; 82: light receiving unit; 83: computer; 84: controller; 85: calculation unit; 86: storage unit; 88: object.

1. A light beam scanning device comprising:
a plurality of light sources that emit a plurality of light beams, wherein each of the plurality of light beams is emitted from a corresponding light source of the plurality of light sources and has a larger light beam diameter in a fast axis direction than in a slow axis direction;
a plurality of beam shapers, wherein each of the plurality of beam shapers is provided for a corresponding light source of the plurality of light sources and shapes a light beam emitted from the corresponding light source;
a scanning mirror that scans the plurality of light beams shaped by the plurality of beam shapers; and
a scanning region correction optical member that corrects at least one of a plurality of scanning regions formed by the plurality of light beams scanned by the scanning mirror,
wherein each of the plurality of beam shapers includes a first lens and a second lens, and the first lens is disposed closer to a corresponding light source of the plurality of light sources than the second lens,
each of the plurality of beam shapers gives a positive refractive power to a corresponding light source of the plurality of light beams in both the slow axis direction and the fast axis direction, and each of the plurality of beam shapers has a focal length Ff in the fast axis direction and a focal length Fs in the slow axis direction greater than the focal length Ff,
in at least one direction, an incident angle θ1 of a first light beam, which is one of the plurality of light beams, on the scanning mirror when the scanning mirror is positioned in the center of a rotation range of the scanning mirror is different from an incident angle θ2 of a second light beam, which is one of the plurality of light beams, on the scanning mirror when the scanning mirror is positioned in the center of the rotation range of the scanning mirror, and
a distance D₁ between the first lens and the second lens in a first beam shaper which is one of the plurality of beam shapers and shapes the first light beam is different from a distance D₂ between the first lens and the second lens in a second beam shaper which is one of the plurality of beam shapers and shapes the second light beam.

2. The light beam scanning device according to claim 1, wherein
the incident angle θ2 is greater than the incident angle θ1,
the scanning region correction optical member gives a negative refractive power to the second light beam in the slow axis direction, and
the distance D₂ is greater than the distance D₁.

3. The light beam scanning device according to claim 1, wherein
the incident angle θ2 is greater than the incident angle θ1,
the scanning region correction optical member gives a positive refractive power to the second light beam in the slow axis direction, and
the distance D₂ is smaller than the distance D₁.

4. The light beam scanning device according to claim 1, wherein
the first lens has a positive refractive power in the fast axis direction,
the second lens has a positive refractive power in the slow axis direction, and
a focal length F2s of the second lens in the slow axis direction is greater than a focal length F1f of the first lens in the fast axis direction.

5. The light beam scanning device according to claim 4, wherein
the second lens has a zero refractive power in the fast axis direction.

6. The light beam scanning device according to claim 4, wherein
the first lens has a negative refractive power in the slow axis direction.

7. The light beam scanning device according to claim 4, wherein
a divergence angle of the light beam incident on the first lens in the slow axis direction is smaller than a divergence angle of the light beam incident on the first lens in the fast axis direction, and
a divergence angle of the light beam incident on the second lens in the slow axis direction is greater than a divergence angle of the light beam incident on the second lens in the fast axis direction.

8. The light beam scanning device according to claim 1, wherein
each of the plurality of light sources is a multi-mode laser diode, and
an emitter width of the multi-mode laser diode in the slow axis direction is greater than an emitter width of the multi-mode laser diode in the fast axis direction.

9. The light beam scanning device according to claim 1, wherein
each of the plurality of light beams incident on the scanning region correction optical member has a light beam diameter in the fast axis direction and a light beam diameter in the slow axis direction, and
the light beam diameter in the fast axis direction is smaller than the light beam diameter in the slow axis direction.

10. The light beam scanning device according to claim 1, wherein
the scanning region correction optical member is a lens having a free-form surface or a mirror having a free-form surface.

11. The light beam scanning device according to claim 1, wherein
an amount of change in a spread angle given to the first light beam by the scanning region correction optical member is different from an amount of change in the spread angle given to the second light beam by the scanning region correction optical member.

12. The light beam scanning device according to claim 1, wherein
the plurality of light sources includes a first light source, a second light source, and a third light source,
an incident angle of the light beam emitted from the first light source to the scanning mirror is different from at least one of an incident angle of the light beam emitted from the second light source to the scanning mirror or an incident angle of the light beam emitted from the third light source to the scanning mirror.

13. The light beam scanning device according to claim 1, wherein
the at least one direction is one direction perpendicular to a rotation axis of the scanning mirror, a direction in which a difference between the incident angles of the plurality of light beams on the scanning mirror is the largest, or a longitudinal direction of the plurality of scanning regions.

14. The light beam scanning device according to claim 1, wherein
the plurality of scanning regions are more extended than each of the plurality of scanning regions.

15. The light beam scanning device according to claim 1, wherein
the plurality of scanning regions have a plurality of centers,
each of the plurality of centers is a center of a corresponding scanning region among the plurality of scanning regions, and
the plurality of centers are different from each other in position.

16. A distance measuring device comprising:
the light beam scanning device according to claim 1;
a light receiving unit that receives return light beams generated when an object is irradiated with light beams output from the light beam scanning device; and
a calculation unit that calculates a distance to the object based on the received return light beams.
